(19) United States
(12) Patent Application Publication
(10) Pub. No.: US 2010/0014225 A1
(43) Pub. Date: Jan. 21, 2010

(54) Imaging Grid Encasement

(76) Inventors: Leo Reina, Cary, IL (US); James Sorgani, Cary, IL (US)

Correspondence Address: CLIFFORD H. KRAFT, 320 ROBIN HILL DR., NAPERVILLE, IL, 60540, US

(21) Appl. No.: 12/492,626

(22) Filed: Jun. 26, 2009

Related U.S. Application Data
(60) Provisional application No. 61/133,208, filed on Jun. 26, 2008.

(51) Int. Cl. H05K 5/00

(52) U.S. Cl. 361/679.01

(57) ABSTRACT

An improved X-ray grid handler or grid encasement device having built-in extra-strong handles and a way of positively locking the grid into the encasement device. The encasement device can optionally have a spring-loaded trapping and ejection mechanism to hold the grid or imaging medium and free it when desired.

This application is related to, and claims priority from, U.S. Provisional patent application No. 61/133,208 filed Jun. 26, 2008. Application No. 61/133,208 is hereby incorporated by reference.

### BACKGROUND

1. Field of the Invention

The present invention relates generally to imaging grids such as X-ray grids and more particularly to an imaging grid encasement that allows easy and safe transport and use of the grid.

2. Description of the Prior Art

Imaging grids, especially X-ray grids are special filters that improve radiographic images and protect imaging surfaces. The grid generally contains metal or fiber filler strips that help prevent ghost and secondary images which produce unwanted noise in the latent image. X-ray cassettes using film, or digital cassettes using an imaging plate are inserted behind such a grid before use. Films and plates come in different sizes requiring grids of compatible sizes such as 10×12 in., 24×30 cm, 17¼×18⅞ in., 18×18 in. and larger. Grids are typically heavy and fragile, and they can be difficult to transport and manipulate. Presently available grid handlers have light duty surface mounted and easily broken handles creating a danger of damage to equipment or possible injury. Also, such devices have no way to lock the grid into the device also causing accidents where a grid can fall out and be damaged or cause injury to a user.

It would be advantageous to have a method and device for easily handling a grid, where the grid could be placed in an encasement or holder without danger of falling out and yet could be easily ejected.

### SUMMARY OF THE INVENTION

The present invention relates to an improved grid handler or grid encasement device having built-in, unbreakable, inseparable, extra-strong handles and a way of positively locking the grid into the encasement device. The present invention also can have a spring-loaded holding mechanism to hold the grid and free it when desired.

### DESCRIPTION OF THE FIGURES

Attention is directed to several drawings that illustrate the features of the present invention:

FIG. 1 shows a top perspective view of an embodiment of the present invention.

FIG. 2 shows a top (or front) view of the embodiment of FIG. 1

FIG. 3 shows a bottom (or back) view of the embodiment of FIG. 1.

Several drawings and illustrations have been presented to aid in understanding the present invention. The scope of the present invention is not limited by what is shown in the figures.

### DESCRIPTION OF THE INVENTION

The present invention relates to a safe, improved grid handler or (and) grid encasement device that can prevent a grid from falling out with extra-strong handles. The present invention can include a positive snap-in method of holding the grid with an optional spring-loaded holding mechanism. The strength and rigidity of the present invention allows grids to be easily handled, protected during transport and easily ejected for use without any danger of damage to the imaging medium or personnel injury. In particular, having handles on both the long and short axis of the grid, allows the device to be extremely easy and convenient to use.

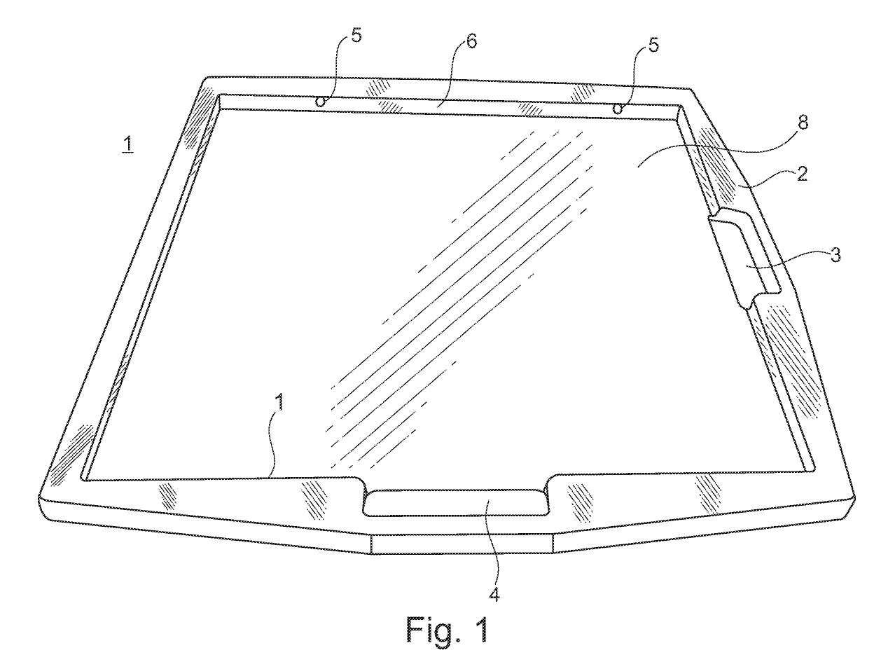

Turning to FIG. 1, a top (or front) perspective view of an embodiment of the present invention, a grid encasement device 1, can be seen. The body of the device includes a flat, recessed surface 8 with a strong frame structure 2 around the outside. The device can be supplied in different sizes to fit different sized grids. A front handle 4 and a side handle 3 makes it very easy for a user to hold and manipulate the device 1. A slot 7 can be placed on a first frame edge and a corresponding slot 6 can be placed on an opposite edge. These slots are typically adapted to snugly hold a grid. At least one, and preferably two spring-loaded pins 5 appear on at least one of the edges of the frame 2. These pins 5 generally hold the grid in the slots 6, 7 by pressing or engaging the grid. Easy release and ejection is accomplished by simply pushing the grid further into the slot 6 thus pushing the pins further in. This causes the grid to clear the other slot 7. Any way of securing the grid in the frame is within the scope of the present invention.

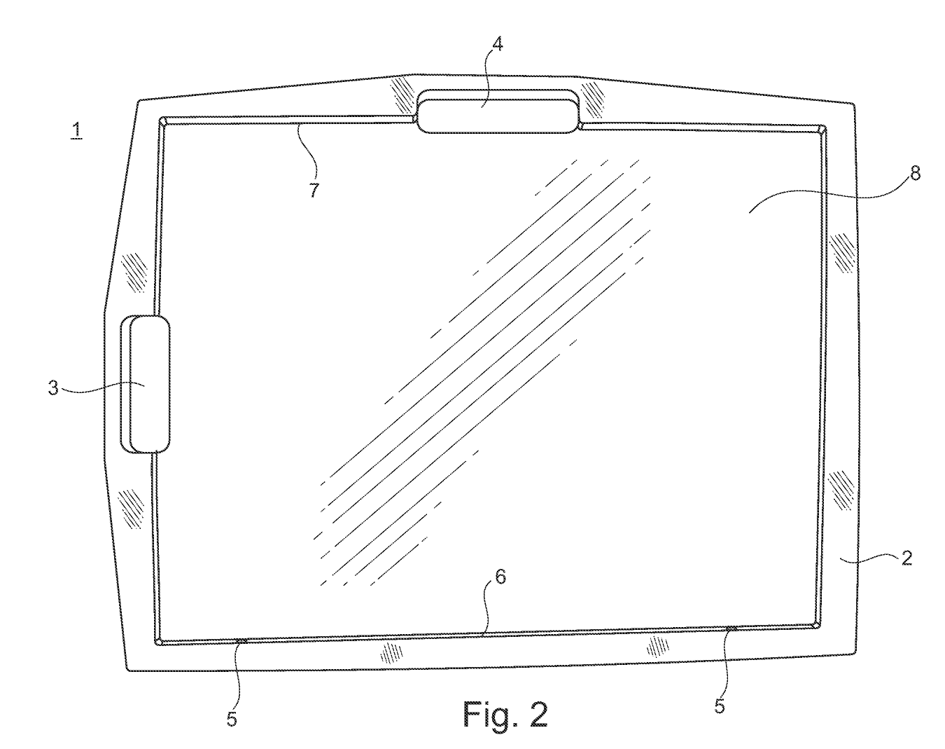

FIG. 2 shows a top (or front) view of the embodiment of FIG. 1. Again, the handles 3, 4, frame edge 2 and flat surface 8 can be seen. The spring-loaded pins 5 can also be seen.

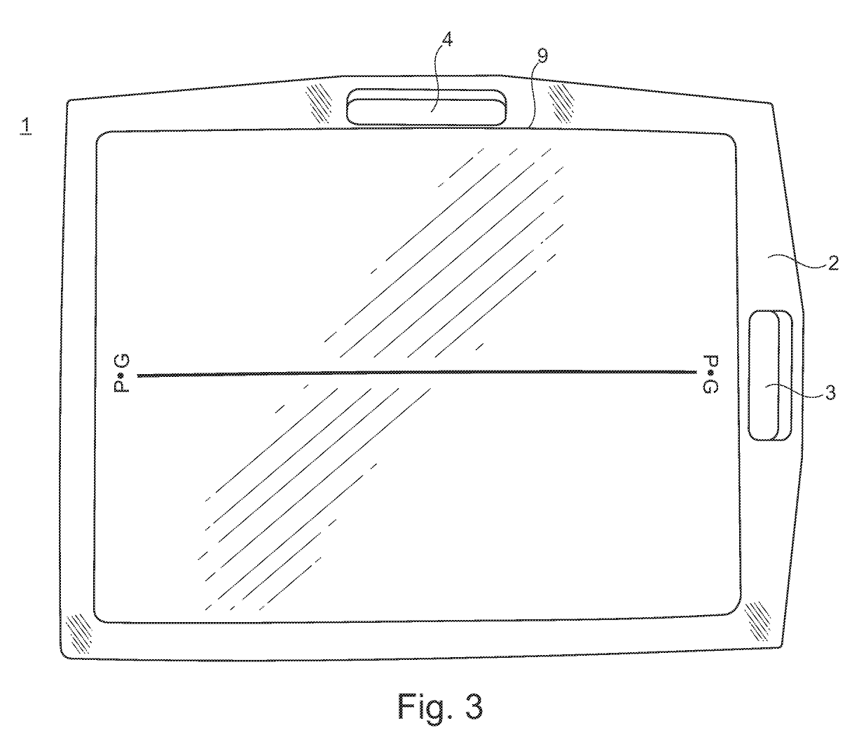

FIG. 3 shows the opposite side of the embodiment of FIGS. 1-2 (bottom or back view). A back surface 9 can be seen along with the frame 2. The handles 3, 4 can be seen from the back side.

The overall shape of the present invention makes it easy to handle imaging grids of all different sizes. Generally the device 1 can be manufactured from a rigid material like plastic or metal using a milled sold frame construction with lightened framing for reduced weight. Lightening can be accomplished by using honeycomb construction since overall weight of such a device is a major consideration. Also, it is very important that the handles 3, 4 be very strong; thus, integrated handles are the preferred construction. This makes the overall presence of handles a desirable asset where it has been undesirable in prior art devices. Generally, the frame, with integral handles, and the top and bottom planes can be milled from HDP plastic using a CNC milling process. Excess material can be taken off of the rail and wherever possible to reduce weight. The device can be screwed and glued together (or put together by any other technique) to produce a final product including the optional spring loaded grid holders.

Several descriptions and illustrations have been presented to aid in understanding the present invention. One skilled in the art will realize that numerous changes and variations are possible without departing from the spirit of the invention. Each of these changes and variations is within the scope of the present invention.

We claim:

1. An X-ray grid encasement device comprising a lightened, generally rectangular frame with a flat bottom that receives and X-ray grid, said frame having a pair of adjacent grooves for receiving an X-ray grid, cassette film or imaging plate, said frame also having at least one built-in strong handle.

2. The device of claim 1 further comprising at least one spring-loaded pin in one of said grooves.

3. The device of claim 1 further comprising a front handle and a side handle.

4. The device of claim 1 wherein said frame is of a size chosen from the group consisting of 10×12 in, 24×30 cm, 17¼×18⅞ in, and 18×18 in.

5. The device of claim 2 further comprising two opposing spring loaded pins on adjacent sides of said frame.

6. The device of claim 1 wherein said frame is of milled solid construction with a lightened frame.

7. The device of claim 2 wherein said slot allows pushing said grid sideways against said spring-loaded pin compressing said spring so that the grid clears the other side and is released.

8. An X-ray grid encasement device comprising a hollowed, generally rectangular frame with a flat bottom that receives and X-ray grid, said frame having a pair of adjacent grooves for receiving an X-ray grid, said frame also having at least one strong handle and least one spring-loaded pin in one of said grooves.

9. The device of claim 8 further comprising a front handle and a side handle.

10. The device of claim 8 wherein said frame is of a size chosen from the group consisting of 10×12 in, 24×30 cm, 17¼×18⅞ in and 18×18 in.

11. The device of claim 8 further comprising two opposing spring loaded pins on adjacent sides of said frame.

12. The device of claim 8 wherein said frame is of milled solid construction with a hollowed frame.

13. The device of claim 8 wherein said slot allows pushing said grid sideways against said spring-loaded pin compressing said spring so that the grid clears the other side and is released.

14. An imaging grid encasement device comprising:
a hollowed, generally rectangular frame of milled solid construction with a flat bottom, the frame containing a grove adapted to receive said imaging grid into said grove, and wherein the frame also has at least two opposing spring loaded pins adapted to trap the imaging grid in the frame; the frame also having an outside flange with two handles disposed at ninety degrees; and wherein the slot in said frame allows pushing the grid sideways against one of the spring-loaded pins compressing the spring so that the grid clears the other side and is released.

15. The device of claim 14 wherein said frame is of a size chosen from the group consisting of 10×12 in, 24×30 cm, 17¼×18⅞ in and 18×18 in.
